(19) United States
(12) Patent Application Publication
(10) Pub. No.: US 2016/0077660 A1
(43) Pub. Date: Mar. 17, 2016

(54) Underwater Touchpad

(71) Applicants: Frederick E. Frantz, Raleigh, NC (US); Mary D. Frantz, Raleigh, NC (US)

(72) Inventors: Frederick E. Frantz, Raleigh, NC (US); Mary D. Frantz, Raleigh, NC (US)

(21) Appl. No.: 14/854,893

(22) Filed: Sep. 15, 2015

Related U.S. Application Data
(60) Provisional application No. 62/051,070, filed on Sep. 16, 2014.
(60) Provisional application No. 62/062,303, filed on Oct. 10, 2014.

(51) Int. Cl. G06F 3/041; H03K 17/96; A63B 71/06

(52) U.S. Cl. CPC G06F 3/0416; G06F 3/0414; G06F 3/0412; A63B 71/0686; H03K 17/964; G06F 2203/04103

(57) ABSTRACT

An underwater touchpad with optional visual information display especially suitable for swimming event timing and training sessions is provided with piezoresistive force sensors, signal processing circuitry, and signaling outputs. By replacing underwater electrical contacts found in some touchpad designs, problems with leaking water and ambient pressure sensitivity are addressed. By replacing accelerometers found in some other touchpad designs, new data can be gleaned from the pressure of the touch, for example. Optionally, the touchpad may also be provided with an integrated display capability to highlight areas to be touched, to provide timing feedback, and other information useful both in training and in competition.

### CLAIM OF BENEFIT TO EARLIER FILING DATE(S)

This non-provisional patent application claims benefit of the filing dates of provisional patent application 62/051,070, our docket FGPFMF2014A1P, filed on Sep. 16, 2014, and provisional patent application 62/062,303, our docket FGPFMF2014A2P, filed on Oct. 10, 2014.

### FEDERALLY SPONSORED RESEARCH AND DEVELOPMENT STATEMENT

None.

### MICROFICHE APPENDIX

Not applicable.

### INCORPORATION BY REFERENCE

None.

### FIELD OF THE INVENTION

This invention relates generally to methods, systems, computer program products and automated processes for sensing a touch of a user in an underwater environment, and particularly to detecting the touch of a swimmer in a swimming pool.

### BACKGROUND OF INVENTION

According to “How Do Swimming Touch Pads Work?” by Michele M. Howard (Oct. 14, 2013), the first swimming touch pad was invented by Bill Parkinson, a University of Michigan professor of physics, in 1957. By 1962, the use of touchpads to automatically stop swimming competition lane timers had been adopted for NCAA swimming competitions. In 1968, the same design was used in the Olympic Games in Mexico City, Mexico. Size and configurations of modern swimming touch pads have been standardized according by the Federation Internationale de Natation (FINA).

### SUMMARY OF THE EXEMPLARY EMBODIMENTS OF INVENTION

An underwater touchpad with optional visual information display especially suitable for swimming event timing and training sessions is provided with piezoresistive force sensors, signal processing circuitry, and signaling outputs. By replacing underwater electrical contacts found in some touchpad designs, problems with leaking water and ambient pressure sensitivity are addressed. By replacing accelerometers found in some other touchpad designs, new data can be gleaned from the pressure of the touch, for example.

Optionally, the touchpad may also be provided with an integrated display capability to highlight areas to be touched, to provide timing feedback, and other information useful both in training and in competition.

### BRIEF DESCRIPTION OF THE DRAWINGS

The drawings provide illustration to the accompanying disclosure of the one or more exemplary embodiments.

FIG. 1 shows an arrangement of components of one available embodiment according to the present invention.

FIG. 2 illustrates the electronic sub-system of the exemplary arrangement of FIG. 1.

FIG. 3 depicts a generalized computer architecture suitable for performing a process by a processor under the programmatic control of program instructions.

### DETAILED DESCRIPTION OF EMBODIMENT(S) OF THE INVENTION

The present inventors have recognized an unsatisfied need in the art of swimming touchpads as described in the following paragraphs. A standard touchpad used for automatic timing in competitive swim events and training is designed to function as a large switch. The internal components of the devices available on the market today detect the force of contact from the swimmer and close an electrical connection that is an input to the timing system. The devices are placed in the water during the event and can be removed for storage when not in use to protect them from damage. Touchpads such as these are sealed to prevent water from entering the device and causing damage, potentially causing shorts in the electrical connections which would produce false touch events.

Due to the sealed construction of the unit, the ambient air pressure can impact the force required by the swimmer to make the connection, so equalization procedures must be performed to insure proper operation.

The present inventors have recognized this need in the art to provide an improved swimming touchpad sensor which avoids electrical contact shorts due to leaking of water, and which avoids the need to properly equalize ambient pressure.

### System Design of New Swimming Touchpad

The new design includes one or more piezoresistive types of force sensors which are in contact with the surface that is used to detect the touch of a swimmer. The contact from the swimmer applies force to the surface, and the piezoresistive force sensor measures the amount of force applied. Signal conditioning circuitry and processes preferably performed by a microprocessor then determine if a valid touch has been detected. For example, wave action impinging on the surface of the touchpad will be sensed by the piezoresistive force sensors, resulting in a component of the sensors' signals being “noise” unrelated to the touch by a swimmer. However, the touch event on the surface will result in a unique, non-noise signal which can be extracted from the composite signal output of the piezoresistive force sensor and qualified by logical steps performed by the microprocessor to declare the touch to have been detected.

The microprocessor will then output to a circuit which will, preferably, close a contact lead to simulate the same signal to a timing system as previously provided by the touchpads available on the market today. This will allow for backwards compatibility to existing timing systems, and will be less disruptive to the market of installed and already-owned systems in natatoriums.

The following advantages of one or more embodiments of the present invention are provided:
1. The piezoresistive force-based sensor implementation eliminates the mechanical operation of existing designs and increases durability and reliability.
2. The piezoresistive force sensor-based design can be used with perforated touchpad designs which allow water to flow through the pad.
3. The use of multiple piezoresistive force sensors will support multi-zone touch areas on the pad for training.
4. Touch detection is based on static pressure and does not depend on the rate of change, which is a limitation of accelerometer-based devices.
5. The use of piezoresistive force sensors can provide data to measure the force on the pad during turns and backstroke starts for training, which is useful information that is unavailable from electrical-connection based touch pads.
6. Touch detection can be indicated by visual or audio feedback on the touchpad.
7. Visual and audio information can be provided on the touchpad for training and competition. This includes pacing, false starts, and touch validation.
8. Transparent material can be used for the touch surface to provide visibility to visual information.
9. Output from the touchpad can be connected to the timing system using wired or wireless interfaces.
10.The output from the touchpad can be configured to operate with existing switch-type touchpad systems.
11. Signal processing methods can reject false touches created by waves in the pool.
12.The ambient air pressure has no impact on the function of the piezoresistive force sensor-based pad, and the microprocessor can adjust for all other ambient conditions.
13. Detection of changes in pressure on the touch surface will eliminate the need for absolute calibration and compensate for changes over time.
14. The use of solid state components allows construction techniques that eliminate internal air pockets that cause existing designs to float if not weighted properly. This can also reduce the overall weight of the pad.
15. A touchpad with active circuitry can include a temperature sensor for training data.
16. Touchpad construction and durability may allow new options for mounting the devices, including permanent installation or integration into the pool wall.

### In-Pool Configuration of Components

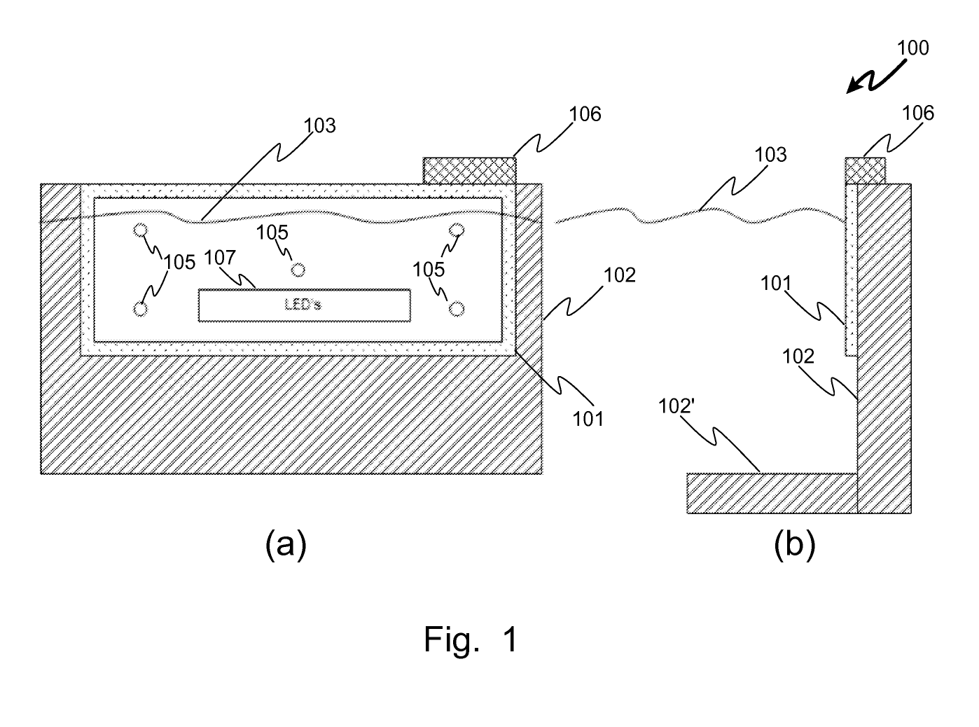

Referring now to FIG. 1, a front view (a) of a configuration of components according to at least one embodiment of the present invention is shown as a swimmer might view it upon approach to touch the touchpad (101) mounted on a pool side wall (102). The touchpad (101) is provided with one or more piezoresistive force sensors (105), optionally spread across the surface of the touchpad or between elements of the surface of the touchpad. A cut-away side view (b) is also provided showing the mounting or hanging of the touchpad (101) on the wall (102) above the floor (102′) of the pool and preferably mostly below the water line (103).

One or more optional display elements, such as light emitting diodes (LEDs) (107) may also be provided on the touchpad to provide various forms of swimmer information as previously discussed.

The piezoresistive force sensor output(s) is/are sensed by an electronics unit (106) which is preferably, but not necessarily, located above the water line (103) in the pool (102, 102′).

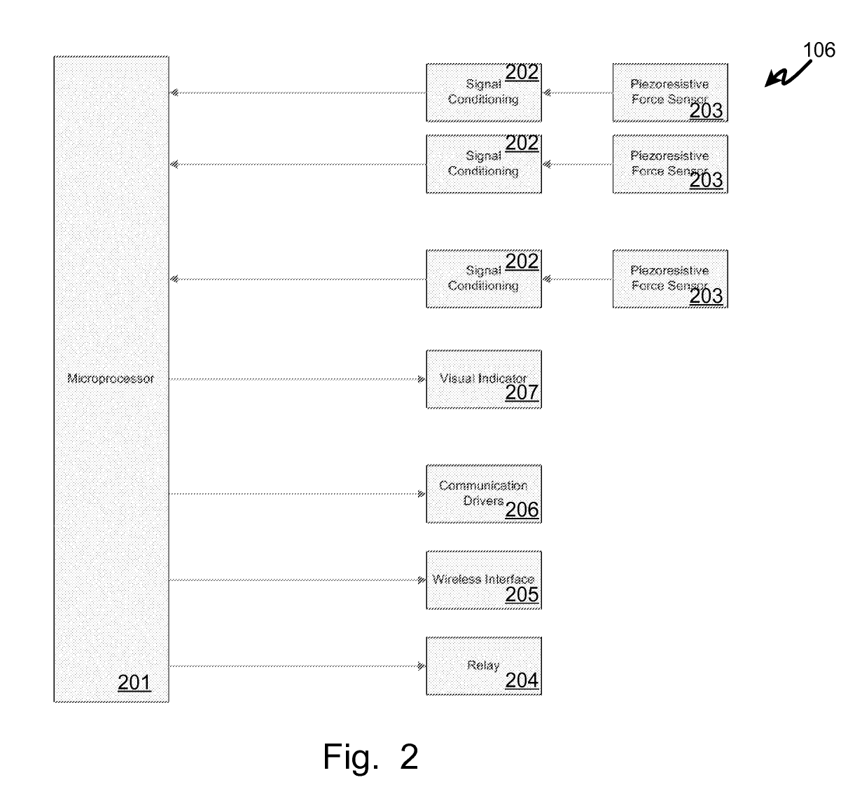

Referring now to FIG. 2, details of the electronics (106) are shown, including a microprocessor (201) for executing firmware to perform a process, and one or more inputs from signal conditioning (202) electronics, such as anti-aliasing sampling filters, which are in turn fed by the outputs from one or more piezoresistive force sensors (203). This particular microprocessor is provided either with internal analog-to-digital conversion (ADC) circuitry, or this circuitry may be provided external to the microprocessor. Piezoresistive force sensors with digital outputs may also be used, if available.

When the logical process determines that a touch event has occurred, an output from the microprocessor preferably closes a relay (204), which is sensed by a swim competition timing system. A wireless interface (205), such as a WiFi, Bluetooth or Zigby interface, may also transmit a message or signal regarding the detection of the touch event. Similarly, other communications drivers, such as local area networks, cellular telephone interfaces, near field communications, infrared data arrangement, etc., may be provided to output a signal regarding the detection of a touch event.

### Suitable Computing Platform

The preceding paragraphs have set forth example logical processes according to the present invention, which, when coupled with processing hardware, embody systems according to the present invention, and which, when coupled with tangible, computer readable memory devices, embody computer program products according to the related invention.

Regarding computers for executing the logical processes set forth herein, it will be readily recognized by those skilled in the art that a variety of computers are suitable and will become suitable as memory, processing, and communications capacities of computers and portable devices increases. In such embodiments, the operative invention includes the combination of the programmable computing platform and the programs together. In other embodiments, some or all of the logical processes may be committed to dedicated or specialized electronic circuitry, such as Application Specific Integrated Circuits or programmable logic devices.

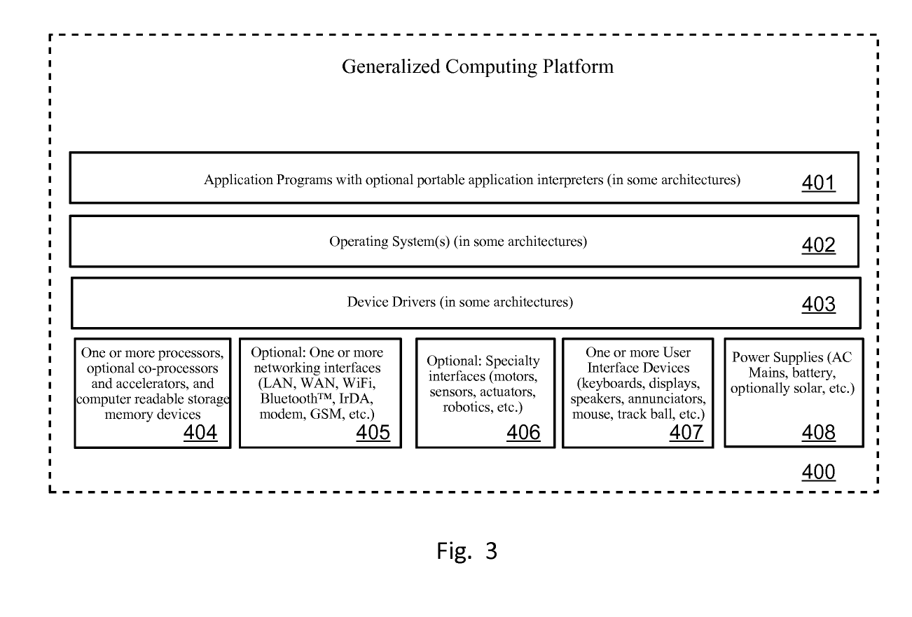

The present invention may be realized for many different processors used in many different computing platforms. FIG. 3 illustrates a generalized computing platform (400), such as common and well-known computing platforms such as “Personal Computers”, web servers such as an IBM iSeries™ server, and portable devices such as personal digital assistants and smart phones, running a popular operating systems (402) such as Microsoft™ Windows™ or IBM™ AIX™, UNIX, LINUX, Google Android™, Apple iOS™, and others, may be employed to execute one or more application programs to accomplish the computerized methods described herein. Whereas these computing platforms and operating systems are well known and openly described in any number of textbooks, websites, and public “open” specifications and recommendations, diagrams and further details of these computing systems in general (without the customized logical processes of the present invention) are readily available to those ordinarily skilled in the art.

Many such computing platforms, but not all, allow for the addition of or installation of application programs (401) which provide specific logical functionality and which allow the computing platform to be specialized in certain manners to perform certain jobs, thus rendering the computing platform into a specialized machine. In some “closed” architectures, this functionality is provided by the manufacturer and may not be modifiable by the end-user.

The “hardware” portion of a computing platform typically includes one or more processors (404) accompanied by, sometimes, specialized co-processors or accelerators, such as graphics accelerators, and by suitable computer readable memory devices (RAM, ROM, disk drives, removable memory cards, etc.). Depending on the computing platform, one or more network interfaces (405) may be provided, as well as specialty interfaces for specific applications. If the computing platform is intended to interact with human users, it is provided with one or more user interface devices (407), such as display(s), keyboards, pointing devices, speakers, etc. And, each computing platform requires one or more power supplies (battery, AC mains, solar, etc.).

### Conclusion

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof, unless specifically stated otherwise.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

It should also be recognized by those skilled in the art that certain embodiments utilizing a microprocessor executing a logical process may also be realized through customized electronic circuitry performing the same logical process(es). It will be readily recognized by those skilled in the art that the foregoing example embodiments do not define the extent or scope of the present invention.

I/we claim:

1. A touchpad sensor for use in an underwater environment comprising:
at least one touch surface to receive a physical touch by a user;
at least one piezoresistive force sensor communicative with the touch surface, and having a force measurement output;
a signal processor which receives the force measurement output, filters the measurement output to detect a user's touch event and rejects non-touch events, and produces a touch event signal; and
an output to a timing system responsive to the producing of the touch event signal.

2. The touchpad sensor as set forth in claim 1 wherein one or more force sensors comprise a plurality of force sensors organized into zones on the touch surface.

3. The touchpad sensor as set forth in claim 2 wherein the signal processor further filters the measurement outputs according to the zones.

4. The touchpad sensor as set forth in claim 1 wherein the touch surface comprises an area of essentially transparent material.

5. The touchpad sensor as set forth in claim 4 further comprising a visual feedback display to the user through the transparent area.

6. The touchpad sensor as set forth in claim 5 wherein the visual feedback display comprises a timer display.

7. The touchpad sensor as set forth in claim 5 wherein the visual feedback display comprises an indicator of a strength of touch on the pad by the user.

8. The touchpad sensor as set forth in claim 1 wherein the signal processor further filters sensor measurement data to remove variations corresponding to differences in ambient pressure.

9. The touchpad sensor as set forth in claim 1 wherein the signal processor further filters sensor measurement data to remove variations corresponding to differences in wave activity.

10. The touchpad sensor as set forth in claim 1 further comprising a temperature sensor for detecting a temperature of water in which the touchpad sensor is disposed, and in which the signal processor receives the detected temperature and further performs the filtering and detecting of a touch event according to the temperature.

11. The touchpad sensor as set forth in claim 1 wherein the rejected non-touch events comprise wave events impinging on the touch surface.

12. The touchpad sensor as set forth in claim 1 further comprising one or more perforations in the touchpad sensor to eliminate or compensate for air pockets to promote sinking of the unit in water without the use of additional weights.

13. The touchpad sensor as set forth in claim 1 wherein the touch surface is integrated into a wall of a swimming pool.

14. The touchpad sensor as set forth in claim 1 wherein the output to a timing system comprises a switch emulation using a relay closure or other device.

15. The touchpad sensor as set forth in claim 1 wherein multiple outputs are provided for more than one timing system.
